(19) United States
(12) Patent Application Publication
(10) Pub. No.: US 2007/0122941 A1
(43) Pub. Date: May 31, 2007

(54) Terminal device communicating with contact-less IC media, and a communication method performed in the terminal device

(76) Inventors: Michihiro Ota, Saitama-ken (JP); Hiroto Honda, Saitama-ken (JP); Hiroaki Yoshida, Saitama-ken (JP); Hiroaki Shinada, Saitama-ken (JP)

Correspondence Address: FISH & RICHARDSON P.C., P.O. BOX 1022, MINNEAPOLIS, MN, 55440-1022, US

(21) Appl. No.: 11/603,675

(22) Filed: Nov. 22, 2006

(30) Foreign Application Priority Data
Nov. 29, 2005 (JP) 2005-343693
Dec. 16, 2005 (JP) 2005-363301

(51) Int. Cl. H01L 21/66; H01L 21/00; H05K 1/14

(52) U.S. Cl. 438/107; 438/14; 361/737

(57) ABSTRACT

The terminal device of the present invention comprises a transmitting means for transmitting, to a contact-less IC medium, commands and carrier signals used for receiving responses, a receiving means for receiving responses from the contact-less IC medium, and a controlling means for controlling at least one of the transmitting means and the receiving means so as to adjust a maximum distance at which the terminal device can communicate with the contact-less IC medium. The terminal device firstly transmits an inquiry request command from the transmitting means to the contact-less IC medium, and receives an inquiry request response to the transmitted inquiry request command at the receiving means from the contact-less IC medium. Then, the terminal device transmits a data processing command from the transmitting means to the contact-less IC medium, and receives a data processing response to the transmitted data processing command at the receiving means from the contact-less IC medium. The maximum distance at which the terminal device can receive the data processing response is greater than the maximum distance at which the terminal device can receive the inquiry request response.

### BACKGROUND OF THE INVENTION

1. Field of the Invention

The present invention relates to a terminal device that communicates with a contact-less IC medium and a communication method thereof.

AS used herein, the term “contact-less IC medium” means a medium such as a contact-less IC card, a cellular phone or the like, and a portable terminal having mounted thereon an IC chip storing e-cash information including a value and the like and identification information including ID information and the like.

2. Related Background Art

A contact-less IC medium, for example, a contact-less IC card includes an IC chip, which integrates a CPU calculating means used for data processing, control or the like and a memory means and the like for storing data, and an antennae means for performing wireless communication, used for wide purposes such as security and the like including an electric money, an electronic settlement, an individual authentication. In order to perform the abovementioned function, the contact-less IC medium communicates with a terminal device such as a card reader/writer or the like, and processes data obtained in the communication and store the data in the memory means. Thus, the contact-less IC medium receives a carrier signal having various commands or the like sent from the terminal device thereon via the antenna means, and extracts data and a clock such as a command by demodulating the carrier signal. The extracted clock is used for synchronizing between the terminal device and the contact-less IC medium as a reference clock. The CPU calculating means of the contact-less IC medium performs data processing such as updating or the like on data stored with the extracted command. The carrier signal transmitted from the terminal device can only be received within a predetermined range. Unless the abovementioned data exchange is normally performed between the terminal device and the contact-less IC medium, whether data processing such as updating of data is properly performed or not cannot be checked to the contact-less IC medium. Thus, the contact-less IC medium needs to be placed in a predetermined distance from the terminal device for a certain period of time.

For example, Japanese Patent Application Laid-Open No. 2005-236998 discloses a communication system for performing a communication between a card reader/writer including a transmitting unit connected with a transmitting antenna means and a receiving unit connected with a receiving antenna means and a contact-less IC card including a communication circuit for performing modulation/demodulation on the transmitting/receiving antenna means, a power circuit, a control unit and a memory unit. In the communication system, a carrier signal, which is transmitted by the card reader/writer to the contact-less IC card, is used for transmitting data to the contact-less IC card and for supplying power to the power circuit of the contact-less IC card. Thus, a power level needs to be kept to a certain level, and accordingly, the BPSK modulation system, which does not change amplitude, is adapted for the modulation system. Therefore, a distance, at which a carrier signal transmitted from a card reader/writer can be received, i.e., a distance, at which a contact-less IC card and the card reader/writer can communicate with each other, is also kept to a certain distance.

Japanese Patent Application Laid-Open No. 2002-170082 discloses a reader/writer for communicating with a contact-less IC card, wherein, if a distance from the reader/writer to the contact-less IC card is long and a strength of the signal, which the reader/writer receives from the contact-less IC card, is small, a transmitting power is increased; and if a distance from the reader/writer to the contact-less IC card is short and the strength of the signal from the contact-less IC card received by the reader/writer receives is big, the transmitting power is decreased so as to stabilize an operation of the contact-less IC card.

[Patent Document] Japanese Patent Application Laid-Open No. 2005-236998

[Patent Document] Japanese Patent Application Laid-Open No. 2002-170082

### SUMMARY OF THE INVENTION

The two conventional arts can perform data processing with a contact-less IC medium, even if the contact-less IC medium is placed at the maximum distance, within which the contact-less IC medium can communicate, if only a carrier signal from a card reader/writer can be correctly received. In many cases, a user moves the contact-less IC medium near to the card reader/writer and then instantaneously moves the contact-less IC medium away. In such a case, a contact-less IC medium goes outside the maximum distance during a period after the terminal device detects the contact-less IC medium until it completes predetermined processing, leading a problem of causing wrong processing.

The present invention is adapted in view of the abovementioned problems.

The terminal device according to the present invention comprising a transmitting means for transmitting, to a contact-less IC medium, commands and carrier signals used for receiving responses, a receiving means for receiving responses from the contact-less IC medium, and a controlling means for controlling at least one of the transmitting means and the receiving means so as to adjust a maximum distance from the contact-less IC medium, said terminal device; transmitting an inquiry request command and a data processing command from the transmitting means to the contact-less IC medium; and receiving an inquiry request response and a data processing response in response to each of the inquiry request command and the data processing command from the contact-less IC medium by the receiving means; wherein the controlling means adjust a maximum distance at which said terminal device can receive the data processing response to be greater than a maximum distance at which said terminal device can receive the inquiry request response.

Therefore, even if the contact-less IC medium goes away from the terminal device after the terminal device received an inquiry request response from the contact-less IC medium, data processing is properly performed on the contact-less IC medium so that whether the data processing has been performed or not can be checked, as a maximum distance at which the terminal device can receive a data processing response is greater than a maximum distance at which the terminal device can receive an inquiry request response. Although the terminal device of the present invention has the transmitting means for transmitting commands and the transmitting means for transmitting carrier signals integrated together, these means may be adapted separately.

The terminal device according to the present invention increases the maximum distance by causing the controlling means to adjust a reception sensitivity of the receiving means until the terminal device receives the data processing response. Specifically, the reception sensitivity of the receiving means of the terminal device is made small after the terminal device transmits carrier signals added with an inquiry request command by the reception of an inquiry request response to the inquiry request command. Then, the reception sensitivity of the receiving means of the terminal device is increased after the terminal device receives the inquiry request response by the reception of the data processing response from the contact-less IC medium at the latest. Consequently, even if the contact-less IC medium goes away from the terminal device after the terminal device receives the inquiry request response from the contact-less IC medium, data processing can be correctly performed at the contact-less IC medium, as the maximum distance at which the terminal device can receive the data processing response is greater than the maximum distance at which the terminal device can receive the inquiry request response.

The terminal device according to the present invention increases the maximum distance at which the terminal device can receive the data processing response by causing the controlling means to adjust a transmitting output of the transmitting means by the reception of the data processing response. Specifically, a transmitting output of the transmitting means of the terminal device is made small after the terminal device transmits carrier signals added with the inquiry request command by the reception of the inquiry request response from the contact-less IC medium to the inquiry request command, and the transmitting output of the transmitting means of the terminal device is increased after the terminal device receives the inquiry request response by the reception of the data processing response from the contact-less IC medium. Consequently, even if the contact-less IC medium goes away from the terminal device after the terminal device receives the inquiry request response from the contact-less IC medium, data processing can be correctly performed at the contact-less IC medium, as the maximum distance at which the terminal device can receive the data processing response is greater than the maximum distance at which the terminal device can receive the inquiry request response.

The adjustment of the reception sensitivity of the receiving means and the adjustment of the transmitting output of the transmitting means may be performed at the same time or at different times.

The terminal device transmits the data processing command and receives the data processing response, if it transmits the inquiry request command for a plurality of times and receives the inquiry request response at least twice for the inquiry request command. As mentioned above, in order to transmit the data processing command, the terminal device needs to receive the inquiry request response from the contact-less IC medium at least twice. Therefore, a time period for a user of the contact-less IC medium to place the contact-less IC medium within a distance at which the contact-less IC medium can receive the inquiry request command from the terminal device can be prolonged. Then, the terminal device receives the data processing response with a big maximum distance and checks whether the contact-less IC medium properly performed the data processing or not. Therefore, the data processing at the contact-less IC medium can be correctly performed.

The terminal device according to the present invention transmits the data processing command and receives the data processing response, if it transmits the inquiry request command for at least a plurality of times and serially receives the inquiry request response to the inquiry request command for a plurality of times. As mentioned above, in order to transmit a data processing command, the terminal device needs to serially receive the inquiry request response from the contact-less IC medium for at least a plurality of times. Therefore, a time period for a user of the contact-less IC medium to place the contact-less IC medium within a distance at which the contact-less IC medium can receive the inquiry request command from the terminal device can be prolonged. Then, the terminal device receives the data processing response with a big maximum distance and checks whether the contact-less IC medium properly performed the data processing or not. Therefore, the data processing at the contact-less IC medium can be correctly performed.

The method according to the present invention is a method for communicating between a contact-less IC medium and a terminal device comprising a transmitting means for transmitting, to a contact-less IC medium, commands and carrier signals used for receiving responses, a receiving means for receiving carrier signals as responses from the contact-less IC medium, and a controlling means for controlling at least one of the transmitting means and the receiving means so as to adjust a maximum distance at which the terminal device can receive responses from the contact-less IC medium, said method comprising the steps of: (a) transmitting an inquiry request command from the transmitting means to the contact-less IC medium; (b) receiving an inquiry request response to the transmitted inquiry request command at the receiving means from the contact-less IC medium; (c) transmitting a data processing command from the transmitting means to the contact-less IC medium; (d) receiving a data processing response to the transmitted data processing command at the receiving means from the contact-less IC medium; (e) increasing, by said controlling means, a maximum distance at which said contact-less IC medium can receive the data processing command by the step of receiving the data processing response, such that the maximum distance at which said contact-less IC medium can receive the data processing command is greater than the maximum distance at which said terminal device can receive the inquiry request response.

The method according to the present invention is such that the step of increasing, by the controlling means, the maximum distance adjusts the reception sensitivity of the transmitting means by the controlling means by the step of receiving the data processing response so as to change the maximum distance at which the terminal device can receive the data processing response.

The method according to the present invention is such that the step of increasing a maximum distance adjusts the transmitting output of the receiving means by the controlling means by the step of receiving the data processing response so as to change the maximum distance at which the terminal device can receive the data processing response.

The method according to the present invention is such that the step of transmitting an inquiry request command from the transmitting means to the contact-less IC medium comprises the steps of: transmitting an inquiry request command for a plurality of times, and receiving the inquiry request response at least twice for the inquiry request command.

The method according to the present invention is such that the step of transmitting an inquiry request command from the transmitting means to the contact-less IC medium comprises the steps of: transmitting the inquiry request command for at least a plurality of times, and receiving the inquiry request response serially for a plurality of times for the inquiry request command.

Effects thereof are the same as those in the abovementioned apparatus.

### BRIEF DESCRIPTION OF THE DRAWINGS

FIG. 1 is a diagram showing a relationship of a distance between a contact-less IC medium and a terminal device, which changes with time, in a conventional terminal device;

FIG. 2A is a diagram showing a relationship between a contact-less IC medium and a terminal device, which changes with time, based on a first embodiment of the present invention;

FIG. 2B is a diagram showing a relationship between a contact-less IC medium and a terminal device, which changes with time, based on the first embodiment of the terminal device of the present invention;

FIG. 2C is a diagram showing a relationship between a contact-less IC medium and a terminal device, which changes with time, based on a second embodiment of the terminal device of the present invention;

FIG. 3 is a diagram schematically showing a communication system, which includes a contact-less IC medium, the terminal device and the host computer of the present invention;

FIG. 4 is a functional block diagram of the terminal device of the present invention;

FIG. 5 is a circuitry block diagram of the terminal device of the present invention;

FIG. 6 is a diagram showing exchange of signals between a terminal device and a contact-less IC medium;

FIG. 7 is a flowchart showing exchange of signals between a terminal device and a contact-less IC medium; and

FIG. 8 is a flowchart showing exchange of signals between a terminal device and a contact-less IC medium.

### DESCRIPTION OF THE PREFERRED EMBODIMENTS

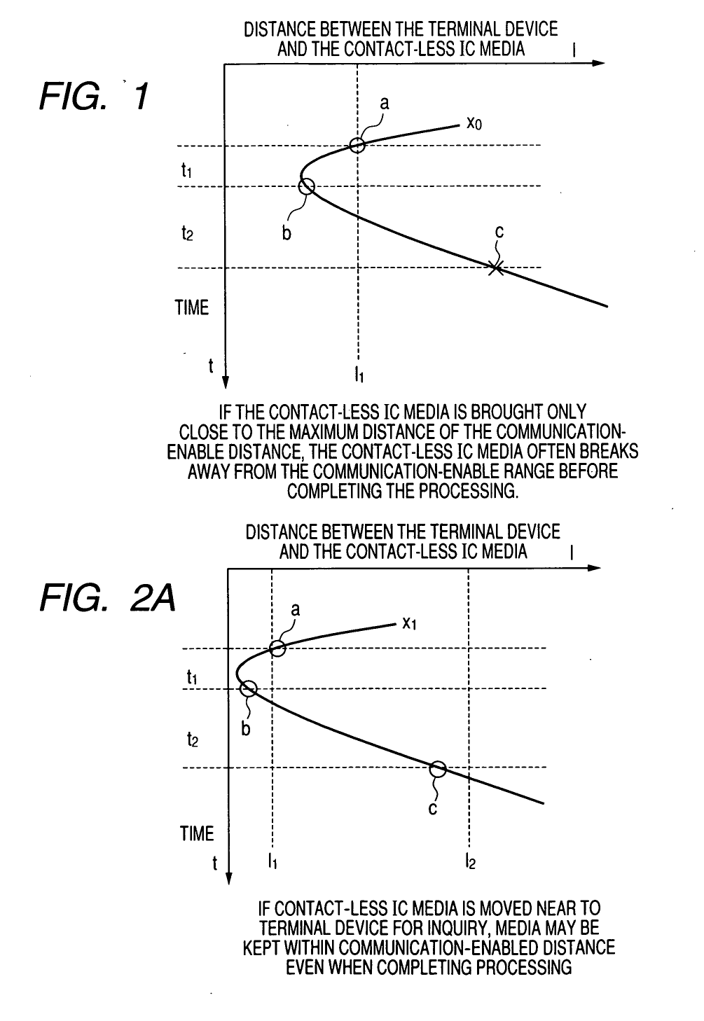

FIG. 1 is a diagram showing a relationship of a distance between a contact-less IC medium and a terminal device, which changes with time, in a conventional terminal device, showing a track of movement of the contact-less IC medium.

Conventionally, a distance for the terminal device to receive an inquiry request response to detect the contact-less IC medium is equal to a distance for the terminal device to receive the data processing response. That it to say, a power level of a carrier signal is the same for all periods.

In FIG. 1, a vertical axis “t” shows a passage of time. The reference character “t₁” shows a time period required for the terminal device to detect a contact-less IC medium. That is to say, “t₁” shows a time period required between when the terminal device transmits the inquiry request command to the contact-less IC medium and when the terminal device receives the inquiry request response from the contact-less IC medium. The reference character “t₂” shows a time period between when the terminal device transmits the data processing command for the contact-less IC medium and when the terminal device receives the data processing response from the contact-less IC medium.

On the other hand, a horizontal axis “I” shows the distance between a terminal device and the contact-less IC medium. The distance is 0 at the left, which is a distance for the contact-less IC medium and the terminal device to contact. The distance between the contact-less IC medium and the terminal device increases toward right. The reference character “I₁” of the horizontal axis shows an effective distance for the terminal device to detect the contact-less IC medium and also shows a distance for a carrier signal to reach from the terminal device. The reference character “X” of FIG. 1 shows a distance between the contact-less IC medium and the terminal device, which changes with time. That is to say, it shows a track of the contact-less IC medium when a user moves the contact-less IC medium near to the terminal device and then away from it.

The point “a” of FIG. 1 shows a time and a distance for the terminal device to reach a distance at which the terminal device can detect the contact-less IC medium. The point “b” of FIG. 1 shows a time and a distance at which the terminal device detects the contact-less IC medium. The point “c” of FIG. 1 shows a time and a distance at which the terminal device cannot receive the data processing response to the contact-less IC medium.

If a user moves the contact-less IC medium near to the terminal device and then away from it along the track denoted by X in FIG. 1, the contact-less IC medium has been away from the maximum distance I₁ when the terminal device is about to receive the data processing command from the contact-less IC medium even if the non-contact IC medium has been detected. (the point “c” in FIG. 1) Therefore, in the case shown in FIG. 1, data processing cannot be performed normally.

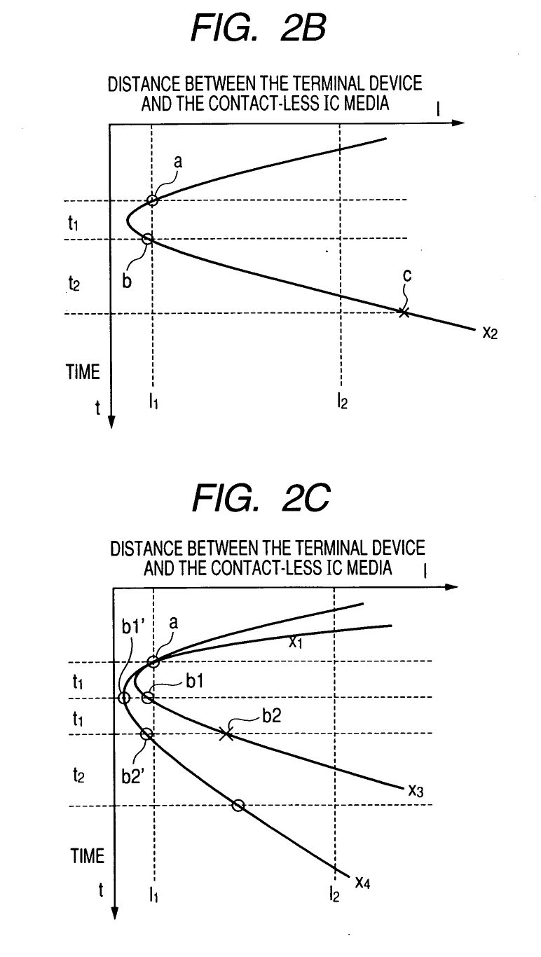

FIGS. 2A, 2B show relationships of distances between the contact-less IC medium and the terminal device, which change with time, based on the first embodiment of the terminal device of the present invention.

In FIGS. 2A, 2B, the vertical axis t₁ shows a time required for the terminal device to detect the contact-less IC medium. That is to say, “t₁” shows a time period required between when the terminal device transmits an inquiry request command to the contact-less IC medium and when the terminal device receives an inquiry request response from the contact-less IC medium. The reference character “t₂” shows a time period required between when the terminal device detects the contact-less IC medium and when the terminal device receives the data processing response from the contact-less IC medium.

The reference character “I₁” shows a distance at which the terminal device can receive an inquiry request response for detecting the contact-less IC medium. The reference character “I₂” shows a distance at which the non-contact IC medium can receive the data processing response, which shows a result of the data processing.

As in FIG. 2A, FIG. 2B, a distance, at which the terminal device can receive the data processing response by increasing the power level of a carrier signal transmitted from the terminal device after the terminal device detects the contact-less IC medium, is greater than a distance at which the terminal device can receive an inquiry request response.

The reference character “X₁” in FIG. 2A shows a relationship of a distance between the contact-less IC medium and the terminal device, which changes with time. The point “a” of FIG. 2A shows a time and a distance for the terminal device reaches the maximum distance at which the terminal device can detect the contact-less IC medium. The point “b” of FIG. 2A shows a time and a distance at which the terminal device detects the contact-less IC medium. The point “c” of FIG. 2A shows a time and a distance, at which the terminal device can receive the data processing response, which shows a result of the data processing the terminal device caused the contact-less IC medium to perform.

The terminal device waits for the contact-less IC medium to approach at a power level of a carrier signal, at which the distance becomes the maximum distance I₁. The terminal device waits for the contact-less IC medium to approach at a power level of a carrier signal, at which the distance becomes the maximum distance I₁. If the contact-less IC medium approaches the terminal device along a track as denoted by X₁ in FIG. 2A, the terminal device can detect the contact-less IC medium only once during the time period t₁. The terminal device based on the first embodiment of the terminal device of the present invention increases the maximum distance by transmitting the data processing command for processing data stored in the contact-less IC medium and increasing the power level of the carrier signal after it detects the contact-less IC medium. Therefore, when the terminal device detects the contact-less IC medium, the contact-less IC medium places close enough to the terminal device, making a room between the place of the contact-less IC medium and the maximum distance I₂ at the moment so that the terminal device can correctly receive the data processing response from the contact-less IC medium.

However, as in FIG. 2A, when a user of the contact-less IC medium slowly moves the contact-less IC medium, the data processing response can be correctly received from the contact-less IC medium, and when the user quickly moves the contact-less IC medium, the data processing response cannot be received correctly from the contact-less IC medium even if the terminal device increases the maximum distance by increasing the power level of the carrier signal after transmitting the data processing command.

FIG. 2B is a diagram showing a case, in which the contact-less IC medium is quickly moved as in the case of FIG. 2A. The reference character “X₂” of FIG. 2B shows a relationship of a distance between the contact-less IC medium and the terminal device, which changes with time. The point “a” in FIG. 2A shows a time and a distance at which the terminal device reaches the maximum distance at which the terminal device can detect the contact-less IC medium. The point “b” in FIG. 2A shows a time and a distance at which the terminal device detects the contact-less IC medium. The point “c” in FIG. 2A shows a time and a distance at which the terminal device cannot receive the data processing response, which shows a result of the data processing the terminal device causes the contact-less IC medium to perform. As such, if a user of the contact-less IC medium quickly moves the contact-less IC medium near to the terminal device and apart from it as shown by the track X₂, the contact-less IC medium has already been away from the maximum distance I₂ when the terminal device is about to receive the data processing command from the contact-less IC medium. (the point “c” of FIG. 2B) Therefore, the processing cannot be performed normally. The terminal device of the second embodiment transmits the data processing command after detecting the contact-less IC medium for at least a plurality of times to solve the problem of the first embodiment.

FIG. 2C is a diagram showing a relationship of a distance between the contact-less IC medium and the terminal device, which changes with time, based on the second embodiment of the terminal device of the present invention. The reference characters X₃, X₄ in FIG. 2C show a relationship of a distance between the contact-less IC medium and the terminal device, which changes with time. The point “a” in FIG. 2C shows that the terminal device reached the maximum distance, at which the terminal device can detect the contact-less IC medium. The point “b1” in FIG. 2C shows a time and a distance, at which the terminal device detects the contact-less IC medium when the contact-less IC medium is quickly moved away from the terminal device. The point “b1′” in FIG. 2C shows a time and a distance at which the terminal device detects the contact-less IC medium. The point “b2” in FIG. 2C shows a time and a distance at which the terminal device cannot detect the contact-less IC medium when the contact-less IC medium is quickly moved away from the terminal device. The “b2′” in FIG. 2C shows a time and a distance, at which the terminal device detects the contact-less IC medium. The point “c” in FIG. 2C shows a time and a distance, at which the terminal device can receive the data processing response, which shows a result of the data processing the terminal device caused the contact-less IC medium to perform.

In FIG. 2C, if a user of the contact-less IC medium quickly moves the contact-less IC medium away from the card reader/writer as shown as track X₃, a time for detecting at least a plurality of contact-less IC media cannot be reserved enough so that a command to be used for processing data stored in the contact-less IC medium cannot be executed. If a user of the contact-less IC medium moves the contact-less IC medium near to the card reader/writer as shown as the track X₄, the contact-less IC medium is detected for at least a plurality of times so that a command to be used in processing data stored in the contact-less IC medium is transmitted.

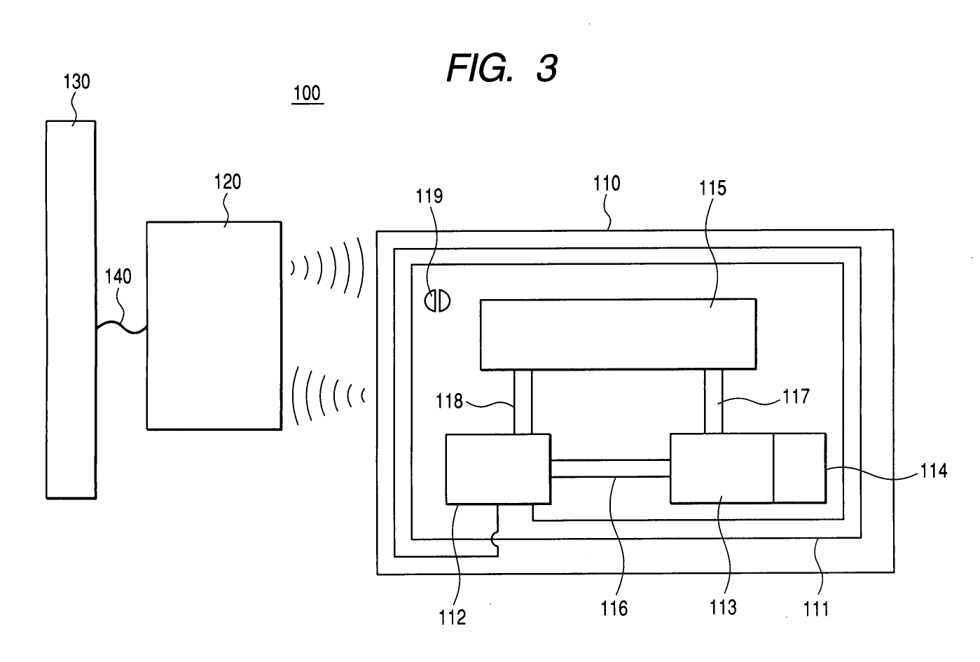

FIG. 3 is a diagram schematically showing a communication system 100, which includes a contact-less IC medium 110, the terminal device 120 and the host computer 130 of the present invention. The contact-less IC medium 110 is described as a contact-less IC card. The contact-less IC medium 110 is in a credit card size, including an antenna means for transmitting/receiving 111, a communication circuit 112, a CPU calculating means 113, a memory means 114, and a power source means 115. The terminal device 120 is connected with a host computer 130 via a bus 140. The host computer 130 may be an automatic ticket-vending machine, an automatic vending machine, a cash register, a POS terminal and the like, but it may be an automatic teller machine (ATM) settled at a bank or the like.

The signal from the terminal device 120 to the contact-less IC medium 110 is received via the antenna means for transmitting/receiving 111 and transmitted to the communication circuit 112. In transmitting the data, the communication circuit 112 encrypts data signal, compresses the encrypted data, modulates the compressed data and adds the data on the carrier signal, then amplifies the data at an amplifier and transmits the data to the antenna means for transmitting/receiving 111, and the data signal is transmitted via the antenna means for transmitting/receiving 111. In receiving the data, the communication circuit 112 demodulates the received data signal, detects a base-band signal, decompresses the demodulated data, decrypts the decompressed data and transmits it to the memory means 114. The antenna means for transmitting/receiving 111 configures a RLC resonance circuit including an inductance, a capacitance, and a resistance element. By making the resistance element as a variable resistance by using a MOSFET and the like, steepness Q of the resonance of the RLC resonance circuit can be adjusted so that the reception sensitivity can be adjusted at the contact-less IC medium 110 side. The communication circuit 112 is connected each other with the CPU calculating means 113 via an interface 116. The CPU calculating means 113 controls the abovementioned series of operations of the communication circuit 112. The communication circuit 112 is connected with the power source means 115 via the interface 118.

The power source means 115 is connected with the CPU calculating means 113 via the interface 117, and connected with the communication circuit 112 via the interface 118, supplying power for driving the CPU calculating means 113 and the communication circuit 112, respectively. The power source means 115 may be a capacitor or a chargeable secondary battery. When the capacitor is used, a signal with a big power cannot be stably generated. On the other hand, when the secondary battery is used, a stable voltage can be applied but the battery soon goes exhausted. When the battery is exhausted, the chargeable secondary battery can be charged via a region 119 with a metal contact. The battery can be charged as it is connected with the cellular phone, for example.

The CPU calculating means 113 is connected with the communication means 112 via the interface 116 and is connected with the power source means 115 via the interface 117. The CPU calculating means 113 is also directly connected with the memory means 114. The CPU calculating means 113 and the memory means 114 may be adapted by independent integrated circuits or may be integrated together in a unit. A standard microcontroller, which can be made at low cost, can be used for the CPU calculating means 113 and the memory means 114. The CPU calculating means 113 not only controls data processing of the communication circuit 112 but also writes data into the memory means 114 and reads data out from the memory means 114.

The memory means 114 stores a user ID of the contact-less medium 110 and the other data. The data can include value data of the e-cash, a product-identification code, or if a user is a factory worker, an electric key, an attendance record or the like. The contact-less IC medium 110 can be used as a money device, for example. The contact-less IC medium 110 can also be an automatic vending machine for electric money or a register at a store. When the contact-less IC medium 110 is used for purchasing a product from an automatic vending machine, the contact-less IC medium 110 can be adapted to read an identification code of the selected product from the memory means 114 and transmit the code. For example, a simple message (short message SMS) including an identification code of the product can be transmitted. In such a case, the product price corresponding to the identification code of the ordered product is subtracted from the value data stored in the memory means 114. A simple program code may be stored and transmitted to the terminal device such as a personal computer or a cellular phone.

The communication circuit 112 processes data received from the terminal device 120 at a receiving part (not shown) and also processes data read from the memory means 114 at a transmitting part (not shown) under the control of the CPU calculating means 113. The data signal received from the terminal device 120 via the transmitting/receiving antenna means 111 is stored in the memory means 114 via the receiving means. On the other hand, the data read out from the memory means 114 is transmitted from the transmitting/receiving antenna means 111 to the terminal device 120 through the transmitting unit. The receiving unit 201 includes an amplifying means, a demodulation means, a decrypting means and a data decompressing means. The receiving unit includes an amplifying means, a modulating means, an encrypting means and a data compressing means.

Data exchange between the contact-less IC medium 110 according to the present invention and the terminal device 120 connected with the host computer 130 is performed according to the procedures below. First, a first carrier signal with a first power level added with an inquiry request command is transmitted from the transmitting antenna means of the terminal device 120 to the contact-less IC medium 110. Here, the inquiry request command includes wide variety of inquiry request commands such as an inquiry request command for requesting inquiry of the contact-less IC medium, an inquiry request command for requesting inquiry of the value (balance data) stored in the contact-less IC medium, an inquiry request command for requesting mutual authentication, and the other inquiry request commands. Alternatively, only the first carrier signal may be transmitted. Usually, a free space has an electric wave impedance given by Z₀=∥E₀∥/∥H₀∥=(μ₀/ε₀)^{1/2}, and the first carrier signal added with the inquiry request command transmitted from the terminal device 120 propagates in the air with the electric wave impedance Z₀. Here, as the contact-less IC medium 110 approaches the terminal device 120, μ₀ and ε₀ in the air change to be μ and ε. That is to say, it can be considered as a model of the transmitting/receiving antenna means 111, which forms an RLC resonance circuit formed by an inductance, a capacitance and a resistance element at the contact-less IC medium side is connected as a load with a free space that is simulated as a distributed constant circuit. The first carrier signal transmitted from the terminal device 120 is modulated again (load modulated) by the transmitting/receiving antenna means 111, which forms the RLC resonance circuit at the connect-less IC medium side, a phase or an amplitude changes according to the electric wave impedance Z=∥E∥/∥H∥=(μ/ε)^{1/2}, and the modulated signal is received by the receiving antenna means of the terminal device 120. The response transmitted back from the contact-less IC medium 110 to the terminal device 120 is called as an inquiry request response.

The terminal device 120, which received the inquiry request response, i.e., the load-modulated carrier signal via the receiving antenna means, determines that the contact-less IC medium 110 is detected once. If the terminal device 120 transmits the first carrier signal added with the inquiry request command for a plurality of times and the load-modulated carrier signal is received for the transmission at least twice, the terminal device 120 determines that it detected the contact-less IC medium 110 and causes the contact-less IC medium 110 to perform data processing.

Data processing relating to paying in the automatic vending machine includes the steps below. As the data processing starts, the terminal device 120 transmits the first carrier signal with a relatively small first power level added with an inquiry request command to the contact-less IC medium 110 by certain cycle. After the terminal device 120 receives an inquiry request response at least twice from the contact-less IC medium 110, the terminal device 120 transmits the data processing command including a product price, which the user of the contact-less IC medium 110 wants to buy, and an instruction for subtracting the product price from the balance stored in the contact-less IC medium 110 added with the first carrier signal with the first power level or the second carrier signal with the second power level to the contact-less IC medium 110. The terminal device 120 increases the power level of the carrier signal from the first level to the relatively big second power level during the period after the terminal device 120 receives the inquiry request response at least twice from the contact-less IC medium 110 by the reception of the data processing response from the contact-less IC medium 110 at the latest. Consequently, the data processing response from the contact-less IC medium 110 is transmitted back with the relatively big second power level modulated. Therefore, the maximum distance of the data processing response increases. Even if a user moves the contact-less IC medium away from the terminal device within the maximum distance of the second carrier signal with a relatively big power level, the terminal device 120 can receive the data processing response from the contact-less IC medium 110. The terminal device 120 also enables the data processing response from the contact-less IC medium 110 to be correctly received by making the reception sensitivity big to increase the maximum distance. Also the adjustment of the reception sensitivity only needs to be performed after the inquiry request response is received from the contact-less IC medium 110 at least twice by the reception of the data processing response from the contact-less IC medium 110 at the latest. The adjustment of the power level and the adjustment of the reception sensitivity may be performed at the same time or at different times. Either of the adjustments may only need to be performed. The contact-less IC medium 110 transmits the data processing response including the result of subtracting the product price from the value stored in the contact-less IC medium 110 added to the carrier signal to the terminal device 120. If the result of the data processing is normal, the terminal device 120 that received the data processing response checks that the contact-less IC medium correctly performs the data processing and discharges the product from the automatic vending machine. If the result of the data processing is not normal, the terminal device 120 stops the data processing and discharges no product from the automatic vending machine.

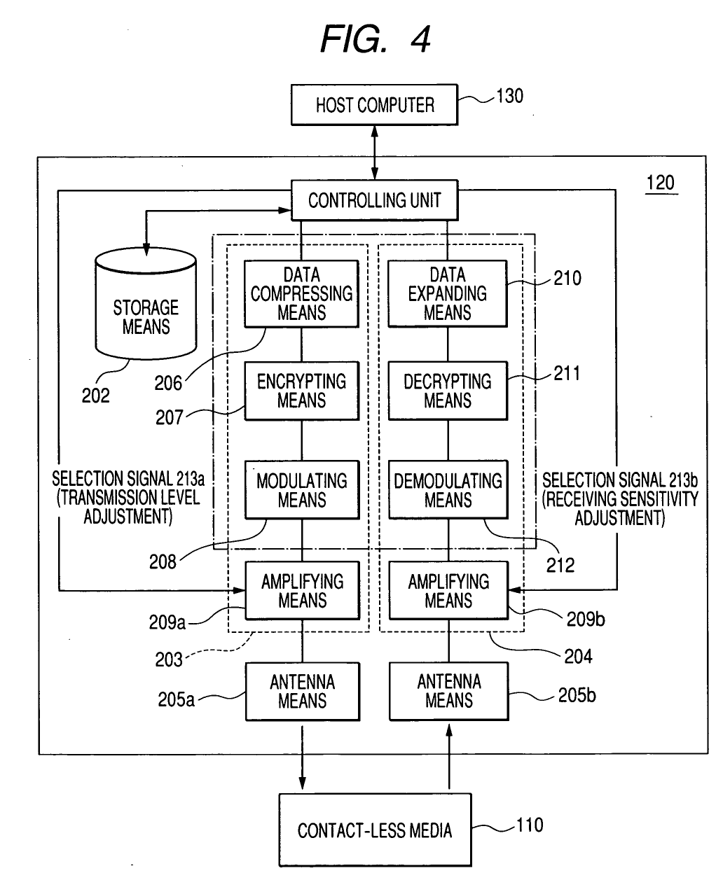

FIG. 4 is a functional block diagram of the terminal device 120 of the present invention. The terminal device 120 includes a controlling unit 201, a storage means 202, a transmitting unit 203, a receiving unit 204, an antenna means for transmitting 205a, and an antenna means for receiving 205b of the terminal device. The transmitting unit 203 includes a data compressing means 206, an encrypting means 207, a modulating means 208 and an amplifying means 209a. The receiving unit 204 includes a data decompressing means 210, a decrypting means 211, a demodulating means 212, and an amplifying means 209b.

The controlling unit 201 of the terminal device has a CPU calculating means (not shown). The controlling unit 201 controls reading of data out from the storage means 202 and writing of data into the storage means 202 and also controls components inside a long and short dashed line of FIG. 3 by executing a software program stored in the storage means 202 on the CPU calculating means. The controlling means 201 of the terminal device exchanges data with the host computer 130. Although the controlling means 201 of the terminal device is shown separately from the storage means 202, it may include the storage means 202 therein. The data signal received from the contact-less IC medium 110 via the antenna means for receiving 205b is processed by the controlling means 201 of the terminal device through the receiving unit 204 and stored in the storage means 202. On the other hand, the data read out from the storage means 202 is transmitted to the contact-less IC medium 110 from the transmitting antenna means 205a through the transmitting unit 203.

When the data is transmitted, the controlling unit 201 of the terminal device reads out data such as the product price or a value of the contact-less IC medium 110 at that moment from the storage means 202. The read out data is subject to data compression prior to encryption. The data compression is performed at the data compressing means 206. The datagram such as the product price corresponding to the product identification code or a value of the contact-less IC medium 110 at the moment is compressed by the function called an encoder. A known hash function is used for the encoder. The data compression is performed so as to remove redundancy in the data by a known method.

The compressed data is encrypted at the encrypting means 207 from the viewpoint of ensuring security. Encryption methods can be classified into a common key encryption method and a public key asymmetric encryption method. The common key encryption method is an (asymmetric) encryption method, in which an encrypting key used for encryption and a decrypting key used for decrypting are the same. As the same key is used for both encryption and the decryption, the encryption key needs to be kept secret at both of the transmitting side and the receiving side. In contrast, the public key encryption method is an encryption method that uses a pair of different keys of an encryption key and a decryption key. In the public key encryption method, a pair of different encryption keys is generated, one of the keys is exposed as an encryption key (public key), and a decryption key (secret key) is managed at the transmitting/receiving side. Consequently, when a user wants to perform an encrypted communication, the user can perform the communication with its contents hidden from the abuser, if the communication contents are encrypted with the public key at the receiving side so that only the secret key at the receiving side can decrypt the communication contents. The RSA method is a public key encryption method, which is most widely used at present. The encrypting means 207 may select either of encryption methods of the common key encryption method and the public key asymmetric method.

The encrypted data is modulated at the modulating means 208 and added to the carrier signal. The modulating means 208 can use, for example, the ASK (amplitude shift keying) method, the FSK (frequency shift keying) method, the PSK (phase shit keying) method and the QAM (quadrature amplitude modulation) method. The data exchanged between the contact-less IC medium 110 and the terminal device 120 is a binary signal of 0 and 1. Therefore, the binary ASK method, the binary FSK method, the BPSK method or the like may be used. The BPSK method has a smaller code error ratio to the same C/N than the other modulation methods. The BPSK method has a constant envelope curve and no information on its amplitude so that it can endure the level fluctuation in the transmission channel.

The output signal modulated by the modulating means 208 is amplified by the amplifying means 209a and transmitted to the contact-less IC medium 110 via the antenna means for transmitting 205a. The control unit 201 of the terminal device adjusts a gain of the amplifying means 209a by using a selection signal 213a to adjust a power level of the carrier signal transmitted from the antenna means for transmitting 205a. The controlling unit 201 of the terminal device adjusts a gain of the amplifying means 209b, which is connected with the antenna for receiving 205b, by using the selection signal 213b to adjust the reception sensitivity of the terminal device 120.

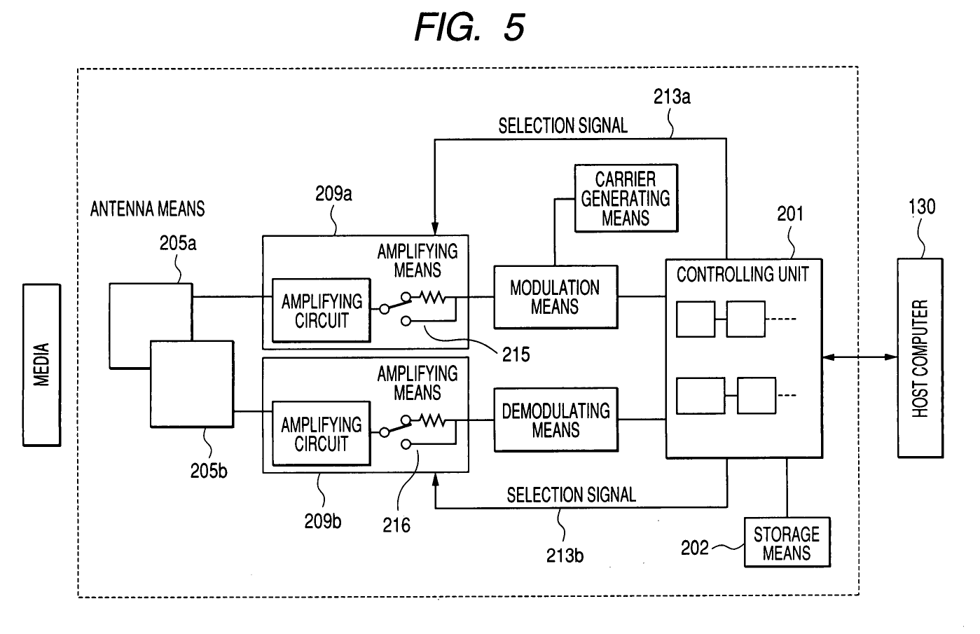

FIG. 5 shows a circuitry block diagram of the terminal device 120 according to the present invention. The control unit 201 executes operations of data compression, data decompression, data encryption, data decryption and the like. The control unit 201 exchanges data with the host computer 130 by communicating with the host computer 130. Further, the control unit 201 writes data to the storage means 202 and reads data from the storage means 202. The data read out from the storage means 202 is transmitted to the modulating means 208. The modulating means 208 is connected with a carrier signal generating means 214. If the data from the storage means 202 is transmitted, the modulating means 208 transmits the data added to the carrier signal from the carrier signal generating means 214 to the amplifying means 209a. If no data is transmitted from the storage means 202, the carrier signal from the carrier signal generating means 214 is transmitted to the amplifying means 209a as it is. The controlling means 201 switches the switching means 215 by using the selection signal 213a. The switching means 215 is connected to an input side of the amplifying circuit 217 and functions as a variable attenuation device. As input impedance of the amplifying means 209a is increased by the switching means 215, a gain of the amplifying means 209a decreases, and as input impedance of the amplifying means 209a is reduced by the switching means 215, a gain of the amplifying means 209a increases. The amplified carrier signal is transmitted via the antenna means for transmitting 205a.

On the other hand, the signal received via the antenna means for receiving 205b is transmitted to the amplifying means 209b. The amplifying means 209b includes the amplifying circuit 218 and the switching means 216, which is connected to an output side of the amplifying circuit 218. The controlling unit 201 switches the switching means 216 by using the selection signal 213b. As the output impedance of the amplifying means 209b is increased by the switching means 216, the gain of the amplifying means 209b increases. As the output impedance of the amplifying means 209b is reduced by the switching means 216, the gain of the amplifying means 209b decreases.

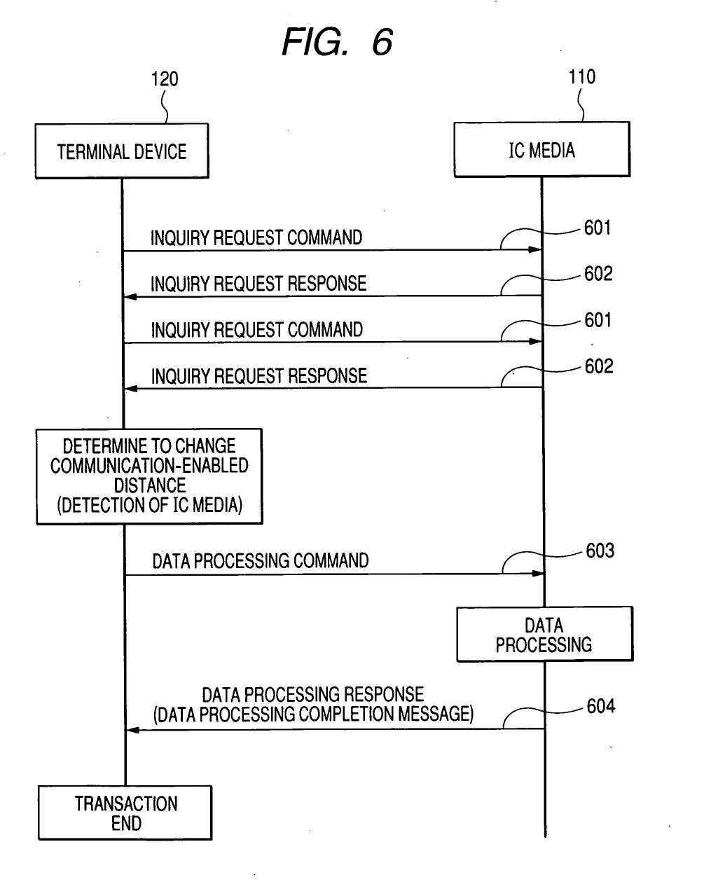

FIG. 6 is a diagram showing exchange of signals between the terminal device 120 and the contact-less IC medium 110 for realizing a track such as X₄ of FIG. 2C. The terminal device 120 transmits a first carrier signal with a relatively small first power level added with the inquiry request command 601 by a certain cycle in the initial state. The inquiry request command widely includes an inquiry request command for requesting an inquiry of the contact-less IC medium, an inquiry request command for requesting an inquiry of the value (balance data) stored in the contact-less IC media, an inquiry request command for requesting mutual authentication and the like as well as the other inquiry request commands. The first carrier signal has a small power level, thus, the contact-less IC medium 110 cannot receive the inquiry request command 601 added to the first carrier signal unless the contact-less IC medium 110 moves near enough to the terminal device 120. When the contact-less IC medium 110 approaches within the maximum range of the first carrier signal, the first carrier signal added with the inquiry request command 601 transmitted from the terminal device 120 is load-modulated by the transmitting/receiving antenna means 111, which makes an RLC resonance circuit at the side of the contact-less IC medium 110. The phase and amplitude of the signal change and the modulated signal is received by the receiving antenna means 205b of the terminal device 120. The load-modulated signal has an inquiry request response 602 on it. The inquiry request response 602 can include the value stored in the contact-less IC medium or the data required for authentication such as an identification number or the like of the contact-less IC medium 110. The terminal device 120, which received the load-modulated carrier signal added with the inquiry request response 602 via the receiving antenna means 205b, determines to detect the contact-less IC medium 110 once. The terminal device 120 transmits the first carrier signal added with the inquiry request command 601 to the contact-less IC medium 110 for a plurality of times and receives the inquiry request response 602 for at least twice for all the transmissions, and then transmits the data processing command added to the first carrier signal or the second carrier signal. The number of times of receiving the inquiry request response 602 may be twice or four times. The terminal device 120 increases the power level of the carrier signal from the first level to the relatively big second power level, after it received the inquiry request response from the contact-less IC medium 110 at least twice by the reception of the data processing response from the contact-less IC medium 110 at the latest. Consequently, the data processing response from the contact-less IC medium 110 is modulated its relatively big second power level and transmitted back. Accordingly, the maximum distance of the data processing response increases. Even if the user moves the contact-less IC medium away in a range within the maximum distance of the second carrier signal with the relatively big power level, the terminal device 120 can receive the data processing response from the contact-less IC medium 110. Also, the terminal device 120 increases the maximum distance by increasing the reception sensitivity so as to enable the data processing response from the contact-less IC medium 110 to be correctly received. The adjustment of the reception sensitivity only needs to be performed after the terminal device 120 received the inquiry request response at least twice from the contact-less IC medium 110 by the reception of the data processing response from the contact-less IC medium 110 at the latest. The adjustment of the power level and the adjustment of the reception sensitivity may be performed at the same time or at the different times. Either of the adjustments may only need to be performed. The contact-less IC medium 110 subtracts the product price from the currently stored value and writes the result in the memory means 114. Then, the contact-less IC medium 110 transmits the data processing response 604 including the result of the subtraction of the product price from the value stored in the contact-less IC medium 110 added to the second carrier signal to the terminal device 120 in order to inform the completion of the data processing. If the result of the data processing is correct, the terminal device 120 received the data processing response 604 checks that the contact-less IC medium correctly performed the data processing and discharges the product from the automatic vending machine. If the result of the data processing is not correct, the terminal device 120 stops the data processing and does not discharge any product from the automatic vending machine.

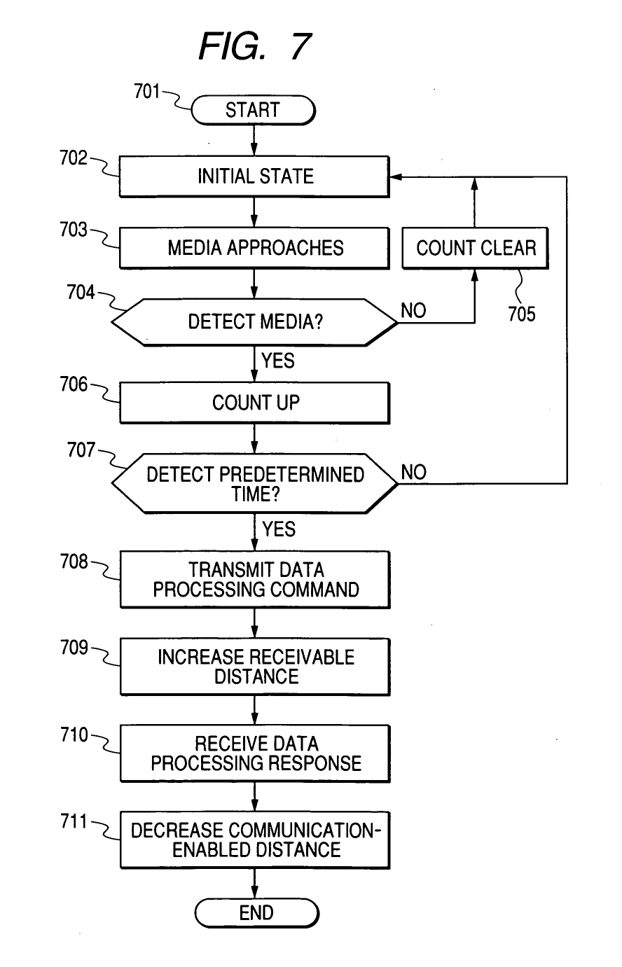

FIG. 7 is a diagram showing a flowchart of exchanging signals shown in FIG. 6. A series of data processing starts at the step 701. At the step 702, the terminal device 120 transmits the first carrier signal with the relatively small first power level added with the inquiry request command 601 by a certain cycle. As the first carrier signal has a small power level, the contact-less IC medium 110 cannot receive the inquiry request command 601 added to the first carrier signal unless the contact-less IC medium moves near enough to the terminal device 120. At the step 703, the contact-less IC medium 110 can receive the inquiry request command 601 as it approaches the terminal device 120. When the contact-less IC medium 110 receives the inquiry request command 601, the contact-less IC medium 110 transmits the inquiry request response 602 to the terminal device 120 in response to the inquiry request command 601.

At the step 704, when the terminal device 120 correctly receives the inquiry request response 602, it determines that it detected the contact-less IC medium 110. When the terminal device 120 does not correctly receive the inquiry request response 602, for example, when a user of the contact-less IC medium 110 abruptly moves the contact-less IC medium 110 away from the terminal device, the terminal device 120 cannot receive the inquiry request response 602 and determines that it did not detect the contact-less IC medium 110. If the terminal device 120 determines that it did not detect the contact-less IC medium 110, the terminal device 120 proceeds to the step 705, where it initializes the number of detecting times to zero, then returns to the step 702 and returns to the initial state. If the terminal device 120 determines that it detected the contact-less IC medium 110, the terminal device 120 proceeds to the step 706 and increments the count of the number of times it serially detected the contact-less IC medium 110 by one. At the step 707, the terminal device 120 determines whether it serially detected the contact-less IC medium 110 for a predetermined number of times. If the terminal device 120 does not determine that it detected the contact-less IC medium 110 for the predetermined times, i.e., if the number of time it serially detected the contact-less IC medium 110 does not reach the predetermined number of times, the terminal device 120 returns to the step 702 and returns to the initial state. If the terminal device 120 determines that it serially detected the contact-less IC medium for the predetermined number of times, the terminal device 120 proceeds to the step 708 and transmits the data processing command 603 added to the first carrier signal or the second carrier signal. Then at the step 709, the terminal device 120 increases the power level of the carrier signal from the first level to the relatively big second power level after receiving an inquiry request response from the contact-less IC medium 110 for at least a plurality of times by the reception of the data processing response from the contact-less IC medium at the latest. Transmission of the data processing command at the step 708 may be before the power level changes at the step 709 or after the power level changes. The terminal device 120 increases the maximum distance by increasing the reception sensitivity so that the data processing response from the contact-less IC medium 110 can be correctly received. The adjustment of the reception sensitivity also only needs to be performed after the terminal device 120 received the inquiry request response from the contact-less IC medium 110 for at least a plurality of times by the reception of the data processing response from the contact-less IC medium 110 at the latest. The adjustment of the power level and the adjustment of the reception sensitivity may be performed at the same time or may be performed at different times. Either of the adjustments may only need to be performed. The number of times of serially receiving the data processing response only needs to be at least twice, or may be three times or four times. In response to the reception of the data processing command 603, the contact-less IC medium 110 receives the data processing command 603 and performs the data processing, i.e., updates the data stored in the contact-less IC medium 110 and transmits the data processing response 604 to the terminal device 120. At the step 710, the terminal device 120 receives the data processing response 604. The terminal device 120 received the data processing response 604 decreases the power level of the carrier signal and decreases the reception sensitivity of the terminal device 120 at the step 711, and returns to the initial state for sending the inquiry request command 601 added to the first carrier signal by a certain cycle. In such a case, the counter counted up at the step 706 is cleared. Alternatively, at the starting at the step 701, the counter may be cleared and the terminal device 120 may enter in the initial state. In the abovementioned embodiment, when the terminal device 120 serially receives the inquiry request response 602 from a particular contact-less IC medium 110 for at least a plurality of times, the terminal device 120 transmits the data processing command 603.

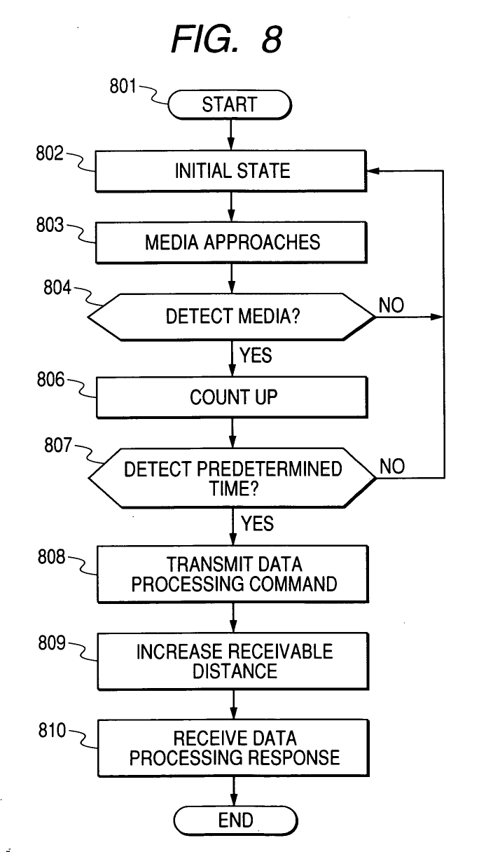

FIG. 8 is a diagram showing a flowchart of exchanging a signal in an alternative embodiment, which is the embodiment shown in FIG. 7 partly corrected. At the step 801, when a user of the contact-less IC medium 110 presses a button or the like of the desired product on the automatic vending machine or the like to start a transaction with the host computer 130 of the automatic vending machine that is connected to the terminal device 120, the terminal device 120 resets the counter, then automatically reduces the power level of the carrier signal, and also reduces the reception sensitivity of the terminal device 120 and enters into the initial state, in which the terminal device 120 transmits the first carrier signal added with the inquiry request command 601. At the step 802, the terminal device 120 is in the initial state, in which the terminal device 120 transmits the first carrier signal with a relatively small first power level added with the inquiry request command 601 by a certain cycle. Although the inquiry request command widely includes an inquiry request command for requesting an inquiry of the contact-less IC medium, an inquiry request command for requesting an inquiry of a value (balance data) stored in the contact-less IC medium, an inquiry request command for requesting mutual authentication, and the other inquiry requesting commands, a user of the contact-less IC medium 110 may transmit the inquiry requesting command attached with data indicating the product price which the user wants to purchase. As the first carrier signal has a small power level, the contact-less IC medium 110 cannot receive the inquiry request command 601 added to the first carrier signal unless the contact-less IC medium 110 sufficiently approaches the terminal device 120. At the step 803, the contact-less IC medium 110 can receive the inquiry request command 601 as the contact-less IC medium 110 approaches the terminal device 120. When the contact-less IC medium 110 receives the inquiry request command 601, the contact-less IC medium 110 transmits the inquiry request response 602 to the terminal device 120 in response to the inquiry request command 601.

At the step 804, when the terminal device 120 correctly receives the inquiry request response 602, it determines that it detected the contact-less IC medium 110. When the terminal device 120 does not correctly receives the inquiry request response 602, for example, when a user of the contact-less IC medium 110 abruptly moves away the contact-less IC medium 110, the terminal device 120 cannot receive the inquiry request response 602 and determines that the contact-less IC medium 110 is not detected. If it is determined that the contact-less IC medium 110 is not detected, the operation returns to the step 802 and the terminal device 120 keeps the initial state. Here, the “initial state” of the terminal device 120 is the state where the terminal device 120 transmits the first carrier signal with a relatively small first power level added with the inquiry request command 601 by a certain cycle. If it is determined that the contact-less IC medium 110 is not detected, the terminal device 120 returns to the step 802 and keeps the initial state, but does not perform the processing at the step 705 described in FIG. 7, i.e., does not reset the number of times for detecting the contact-less IC medium 110 to zero. The terminal device 120 keeps the number of times for detecting the contact-less IC medium 110 as it is and also keeps the initial state. If it is determined that the contact-less IC medium 110 is detected, the terminal device 120 proceeds to the step 806 and increments the count, which indicates the number of times for serially detecting the contact-less IC medium 110, by one. At the step 807, the terminal device 120 determines whether the contact-less IC medium 110 is detected for a predetermined number of times. If it does not determine that the contact-less IC medium 110 is detected for the predetermined number of times, i.e., if the number of times the contact-less IC medium 110 has been detected falls short of the predetermined times, the terminal device 120 returns to the step 802 and keeps the initial state. If it is determined that the contact-less IC medium 110 is detected for the predetermined number of times, the terminal device 120 proceeds to the step 808 and transmits the data processing command 603 added to the first carrier signal or the second carrier signal. At the step 809, the terminal device 120 increases the power level of the carrier signal from the first level to the relatively big second power level after it received the inquiry request response from the contact-less IC medium 110 for a predetermined number of times by the reception of the data processing response from the contact-less IC medium 110 at the latest. The transmission of the data processing command at the step 808 may be performed before or after the power level is changed at the step 809. The terminal device 120 increases the maximum distance by increasing the reception sensitivity to correctly receive the data processing response from the contact-less IC medium 110. The adjustment of the reception sensitivity only needs to be performed after the inquiry request response is received from the contact-less IC medium 110 for a predetermined number of times by the reception of the data processing response from the contact-less IC medium 110 at the latest. The adjustment of the power level and the adjustment of the reception sensitivity may be performed at the same time or at different timings. Either of the adjustments may only need to be performed. The predetermined number of times may be any number of times if only it is twice or more, for example, three times or four times. In response to the reception of the data processing command 603, the contact-less IC medium 110 receives the data processing command 603 and performs the data processing, i.e., it updates the data stored in the contact-less IC medium 110 and transmits the data processing response 604 to the terminal device 120. At the step 810, the terminal device 120 receives the data processing response 604. In the embodiment, the terminal device 120 is described as transmitting the data processing command 63 whether it serially or non-serially receives the inquiry request response 602 from a particular contact-less IC medium 110 for at least twice.

Although the present invention has been described by exemplifying the product purchase through the automatic vending machine, the contact-less IC medium 110 of the present invention can be applied to the transaction through the bank account. The data processing price may be transferred to the user's account of the contact-less IC medium 110 through a sort of banking establishment such as a bank, at which the user has an account. In contrast, the data processing price at the user's account of the contact-less IC medium 110 may be stored in the contact-less IC medium 110. The contact-less IC medium 110 may be used as an entrance and exit storage device. For example, the terminal device 120 may be used as a device for storing the entrance and exit of a particular site such as a factory or an amusement park in the contact-less IC medium 110. In such a case, the data processing command is to write an entrance and exit record.

Those skilled in the art may understand that the application of the present invention has limitless examples. Therefore, the descriptions relate to an embodiment of the present invention, and the spirit of the present invention may not be understood as limited thereto.

What is claimed:

1. A terminal device comprising a transmitting means for transmitting, to a contact-less IC medium, carrier signals used for receiving commands and responses, a receiving means for receiving responses from the contact-less IC medium, and a controlling means for controlling at least one of the transmitting means and the receiving means so as to adjust a maximum distance at which the terminal device can receive responses from the contact-less IC medium, said terminal device;
transmitting an inquiry request command from the transmitting means to the contact-less IC medium;
receiving an inquiry request response to the transmitted inquiry request command at the receiving means from the contact-less IC medium;
transmitting a data processing command from the transmitting means to the contact-less IC medium; and
receiving a data processing response to the transmitted data processing command at the receiving means from the contact-less IC medium;
adjusting, by said controlling means, a maximum distance at which said terminal device can receive the data processing response, such that the maximum distance at which said terminal device can receive the data processing response is greater than a maximum distance at which said terminal device can receive the inquiry request response.

2. The terminal device as set forth in claim 1, wherein the controlling means adjust the reception sensitivity of the receiving means until when the reception of the data processing response at the latest so as to increase the maximum distance at which the terminal device can receive the data processing response.

3. The terminal device as set forth in claim 1, the controlling means adjust the transmission level of the transmitting means until when the reception of the data processing response at the latest so as to increase the maximum distance at which the terminal device can receive the data processing response.

4. The terminal device as set forth in claim 1, wherein the terminal device transmits the data processing command so as to receive the data processing response, if the terminal device transmits the inquiry request commands more than once and receives the inquiry request responses to the transmitted inquiry request commands at least twice.

5. The terminal device as set forth in claim 1, wherein the terminal device transmits the data processing command so as to receive the data processing response, if the terminal device transmits the inquiry request commands more than once and receives the inquiry request responses to the transmitted inquiry request commands more than once in straight succession.

6. A method for communicating between a contact-less IC medium and a terminal device comprising a transmitting means for transmitting, to a contact-less IC medium, carrier signals used for receiving commands and responses, a receiving means for receiving responses from the contact-less IC medium, and a controlling means for controlling at least one of the transmitting means and the receiving means so as to adjust a maximum distance at which the terminal device can receive responses from the contact-less IC medium, said method comprising the steps of;
(a) transmitting an inquiry request command from the transmitting means to the contact-less IC medium;
(b) receiving an inquiry request response to the transmitted inquiry request command at the receiving means from the contact-less IC medium;
(c) transmitting a data processing command from the transmitting means to the contact-less IC medium; and
(d) receiving a data processing response to the transmitted data processing command at the receiving means from the contact-less IC medium;
(e) increasing, by said controlling means, a maximum distance at which said terminal device can receive the data processing response until when the step (d) receiving the data processing response at the latest, such that the maximum distance at which said terminal device can receive the data processing response is greater than a maximum distance at which said terminal device can receive the inquiry request response.

7. The method as set forth in claim 6, wherein the step of (e) increasing, by the controlling means, a maximum distance is characterized by adjusting the reception sensitivity of the receiving means until when the step of (d) receiving the data processing response at the latest so as to change the maximum distance at which the terminal device can receive the data processing response.

8. The method as set forth in claim 6, wherein the step of (e) increasing, by the controlling means, a maximum distance is characterized by adjusting, by the controlling means, the transmission level of the transmitting means until when the step of (d) receiving the data processing response at the latest so as to change the maximum distance at which the terminal device can receive the data processing response.

9. The method as set forth in claim 6, wherein the step of (a) transmitting the inquiry request command further comprises the steps of:
transmitting the inquiry request commands more than once; and
receiving the inquiry request responses to the transmitted inquiry request commands at least twice.

10. The method as set forth in claim 6, wherein the step of (a) transmitting the inquiry request command further comprises the steps of:
transmitting the inquiry request commands more than once; and
receiving the inquiry request responses to the transmitted inquiry request commands more than once in straight succession.
